(19) United States
(12) Patent Application Publication
(10) Pub. No.: US 2026/0060068 A1
(43) Pub. Date: Feb. 26, 2026

(54) CONTACT STRUCTURE WITH LOW CONTACT RESISTANCE AND METHOD OF MANUFACTURING THE SAME

(71) Applicant: Powerchip Semiconductor Manufacturing Corporation, Hsinchu (TW)

(72) Inventors: Shou-Zen Chang, Hsinchu (TW); Ling-Yen Yeh, Hsinchu (TW); Kuei-Fen Chang, Hsinchu (TW); Tzu-Hsuan Chang, Hsinchu (TW); Bi-Xian Wu, Hsinchu (TW); Wei-He Chen, Hsinchu (TW)

(73) Assignee: Powerchip Semiconductor Manufacturing Corporation, Hsinchu (TW)

(21) Appl. No.: 18/959,472

(22) Filed: Nov. 25, 2024

(30) Foreign Application Priority Data
Aug. 20, 2024 (TW) 113131201

(51) Int. Cl. H01L 23/532; H01L 21/3205; H01L 21/768; H01L 23/485; H01L 23/528; H10D 30/47

(52) U.S. Cl. CPC H01L 23/53209; H01L 21/32056; H01L 21/76814; H01L 21/76883; H01L 23/485; H01L 23/5283; H10D 30/47

(57) ABSTRACT

A contact with low contact resistance is provided in the present invention, including a dielectric layer on a substrate, a contact hole formed in the dielectric layer and exposing the substrate, an N-type or P-type metal oxide film on the surface of contact hole, a barrier layer on the metal oxide film, and a contact plug on the barrier layer and filling up the contact hole, wherein a 2DEG or 2DHG is formed in the substrate near the contact surface between the contact and the substrate.

### BACKGROUND OF THE INVENTION

### 1. Field of the Invention

The present invention relates generally to a contact structure, and more specifically, to a contact structure using metal oxide film for reducing contact resistance and method of manufacturing the same.

### 2. Description of the Prior Art

Stable and low-resistance ohmic contact is one of the key factors affecting the performance of semiconductor devices. Conventionally, a good ohmic contact can be achieved by performing high-concentration degenerated doping on the semiconductor material to form a degenerate semiconductor. However, on the one hand, the high-concentration doping process will cause damage to the doping surface and form structural defects, which will affect the electrical properties. On the other hand, the highest stable concentration that can be doped in the semiconductor material will be limited by its lattice strength. In addition, the carrier mobility of semiconductor material would also gradually decrease as the doping concentration increases. Therefore, blindly increasing the degenerate doping concentration to reduce ohmic contact has its limitations in physics and practice. For the power electronic devices as well as currently popular junctionless components that require high carrier mobility and sufficiently low channel resistance, how to further reduce ohmic contact under the existing degenerate doping concentration for improving the performance of devices is a subject for those of skilled in the art to continuously research and develop.

### SUMMARY OF THE INVENTION

In the light of the requirement for high-power components and high-end semiconductor devices, the present invention proposes a novel contact structure and a method of manufacturing the same, featuring a metal oxide film formed on the contact surface between contact and substrate, which may reduce contact resistance and increase carrier mobility.

One aspect of the present invention is to provide a contact structure with low contact resistance set on a substrate and in direct contact with the substrate. The contact structure comprises: a dielectric layer on the substrate; a contact hole formed in the dielectric layer and exposing the substrate; a metal oxide film on a surface of the contact hole and the exposed substrate; a barrier layer on the metal oxide film; and a contact plug on the barrier layer and filling up the contact hole; wherein a two-dimensional carrier gas is formed in the substrate adjacent to a contact surface between the metal oxide film and the substrate.

Another aspect of the present invention is to provide a method of manufacturing a contact structure with low contact resistance, comprising: providing a substrate, and an interlayer dielectric layer is formed on the substrate; forming a contact hole in the interlayer dielectric layer, and the contact hole exposes the substrate; a metal oxide film is formed on a surface of the contact hole, and the metal oxide film is in direct contact with the substrate; forming a barrier layer on a surface of the metal oxide film; and forming a contact plug on the barrier layer, and the contact plug fills up the contact hole so that the contact plug, the barrier layer and the metal oxide film constitute a contact.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-section of a semiconductor substrate with an N-type metal oxide film, a P-type metal oxide film and a corresponding 2D carrier gas formed thereon in accordance with one embodiment of the present invention;

FIG. 2 is an energy band diagram near the interface between the N-type metal oxide film and the substrate in accordance with one embodiment of the present invention;

FIG. 3 is an energy band diagram of an N-type Ga₂O₃ film contacting a substrate in equilibrium state in accordance with one embodiment of the present invention;

FIG. 4 is an energy band diagram of a P-type NiO film contacting a substrate in equilibrium state in accordance with one embodiment of the present invention;

FIG. 5 is a schematic cross-section of a contact structure with low contact resistance in accordance with one preferred embodiment of the present invention;

FIGS. 6-11 are cross-sections illustrating a process flow of manufacturing contact structures with low contact resistance in accordance with one embodiment of the present invention; and

FIGS. 12-15 are cross-sections illustrating a process flow of manufacturing contact structures with low contact resistance in accordance with another embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). In addition, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

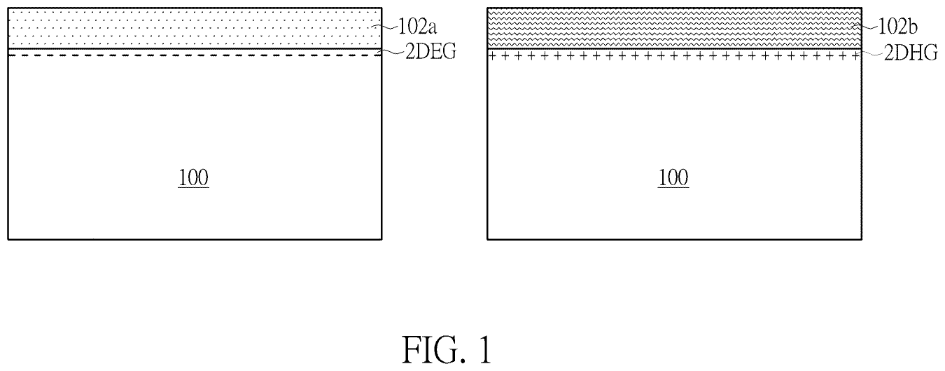

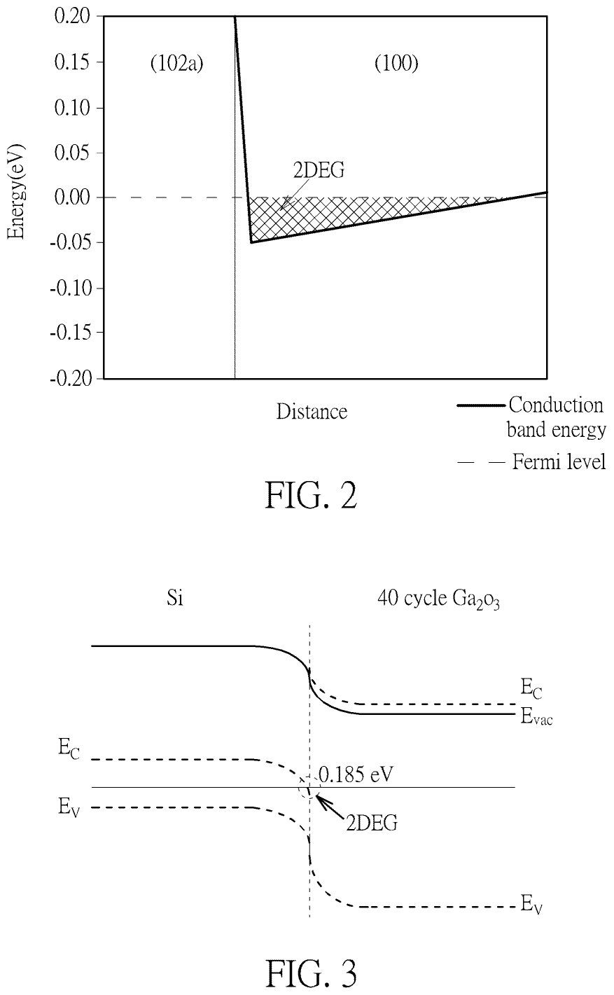

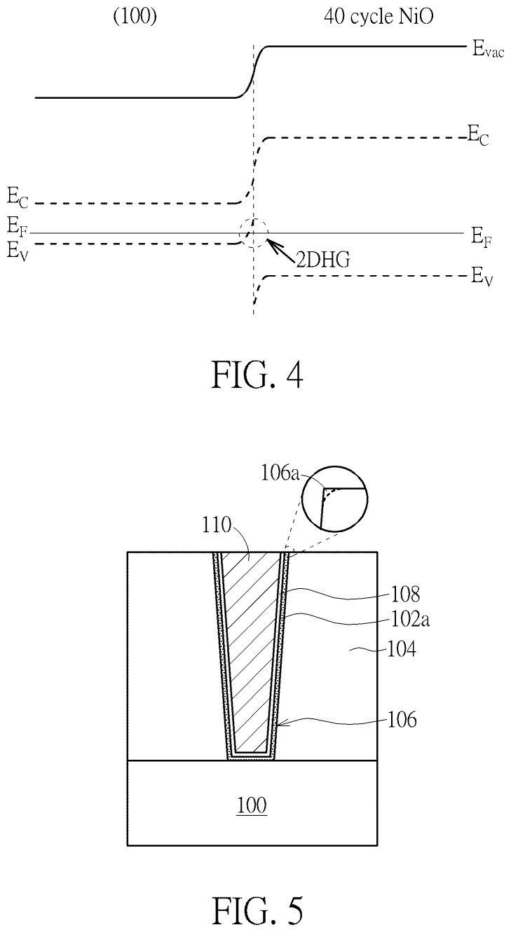

First, please refer to FIG. 1, which is a schematic cross-section of a substrate with an N-type metal oxide, a P-type metal oxide and corresponding two-dimensional carrier gases formed thereon in accordance with one embodiment of the present invention. The operating principle of the present invention may be understood through this figure. As mentioned in prior art, traditional degenerate doping for silicon-based substrate can no longer meet the requirement of low contact resistance and high carrier mobility for high-end components and power devices in current market. In order to further reduce the contact resistance between a semiconductor substrate and the contacts formed thereon and improve the carrier mobility in the contact area, the present invention intends to form a functional metal oxide film on the substrate to achieve the required effect. As shown in FIG. 1, the substrate 100 may be a semiconductor-based substrate, such as a silicon wafer, which can be but not limited to a bare silicon wafer, a P-type doped silicon wafer or N-type doped silicon wafer, depending on the application and requirements. Alternatively, the substrate 100 may also refer to doped wells or doped source/drain terminals formed on a semiconductor substrate, on which metal silicide like nickel silicide (NiSi) may also be formed.

Take the N-type semiconductor on the left as an example, the substrate 100 may be an N-type silicon wafer or an N-type doped region formed thereon, and an N-type metal oxide film 102a is formed on the substrate 100. In the embodiment of present invention, the N-type metal oxide refers to a metal oxide whose work function (Φ) and lattice constant can form a two-dimensional electron gas (2DEG) in the substrate 100 adjacent to the contact surface. Among them, the 2DEG is an electron accumulation layer that can function as a conductive channel near the contact surface. The cause of 2DEG is that the lattice mismatch and stress of the heterojunction between the N-type metal oxide film 102a and the substrate 100 would form a net polarization electric field there when the two components contact each other. Corresponding positive and negative polarization charges will be generated on both sides of the junction. The charges at the side close to the substrate 100 form the electron accumulation layer, representing an increase in the concentration of electrons as carriers in the substrate 100, which helps to significantly reduce the contact resistance.

Furthermore, regarding the energy band of gallium oxide (Ga₂O₃) contacting a silicon substrate, a step difference exists inherently between the bottom lines of conduction bands of the N-type metal oxide film 102a and the substrate 100. This step difference plus a large amount of polarization charges accumulated at the aforementioned interface will bend the bottom lines of conduction band, forming a two-dimensional quantum potential well with an energy lower than the Fermi level (ex. E_{C}<E_{F} near the contact surface) under energy band equilibrium (that is, the Fermi levels are aligned), and the polarization electrons accumulated in the substrate 100 are limited to perform two-dimensional movement only along the plane parallel to the junction in the potential well, which is an ideal conductive channel capable of significantly increasing the electron mobility, improving the carrier mobility reduced by conventional degenerate doping in silicon substrates. In the embodiment of present invention, the N-type metal oxide film 102a may include gallium oxide (Ga₂O₃), zinc oxide (ZnO), tin oxide (SnO₂), indium oxide (In₂O₃), titanium oxide (TiO₂), tungsten oxide (WO₃), indium tin oxide (ITO) and molybdenum oxide (MoO₃), etc., which are formed through multiple reactions and cycles of atomic layer deposition (ALD). This film may be applied in N-type semiconductors or P-type semiconductors to achieve the effect of reducing contact resistance and increasing carrier mobility, especially in the application for N-type semiconductors, for example as a contact interface for source/drain terminals of NMOS devices.

With similar mechanism, take the P-type semiconductor on the right as an example, the P-type metal oxide film 102b refers to a metal oxide whose work function (Φ) and lattice constant can form a two-dimensional hole gas (2DHG) in the substrate 100 adjacent to the contact surface. Among them, the 2DHG is a hole accumulation layer that can function as a conductive channel near the contact surface, which may increase the concentration of holes as carriers in the substrate 100, significantly reducing the contact resistance.

Furthermore, regarding the energy band of nickel oxide (NiO) contacting a silicon substrate, a step difference exists inherently between the bottom lines of conduction bands of the P-type metal oxide film 102b and the substrate 100. This step difference plus a large amount of polarization charges accumulated at the aforementioned interface will bend the bottom lines of conduction band, forming a two-dimensional quantum potential well with an energy higher than the Fermi level under energy band equilibrium, and the polarization holes accumulated in the substrate 100 are limited to perform two-dimensional movement only along the plane parallel to the junction in the potential well, which is an ideal conductive channel capable of significantly increasing the hole mobility, improving the carrier mobility reduced by conventional degenerate doping in silicon substrates. In the embodiment of present invention, the P-type metal oxide film 102b may include nickel oxide (NiO), copper oxide (Cu₂O), cobalt oxide (Co₃O₄), chromium oxide (Cr₂O₃) or silver oxide (Ag₂O), etc., which may be applied in N-type semiconductors or P-type semiconductors to achieve the effect of reducing contact resistance and increasing carrier mobility, especially in the application for P-type semiconductors, for example as a contact interface for source/drain terminals of PMOS devices.

Furthermore, regarding the aforementioned N-type metal oxide film 102a of present invention, it application is not limited on silicon substrates, but can also be applied on other types of substrates, for example on indium gallium zinc oxide (IGZO) substrate as one of the candidates for the fourth generation oxide semiconductor material. From the perspective of energy band, the work function of IGZO (about 4.37 eV) is larger than that of P-type silicon (3.87 eV), which is easier to form a 2DEG channel after contacting with the N-type metal oxide film 102a, so it is also suitable for contacting with the N-type metal oxide film 102a in the present invention to produce an interface with low contact resistance.

Please refer to FIG. 5, which is a schematic cross-section of a contact structure with low contact resistance in accordance with one preferred embodiment of the present invention. An N-type semiconductor is used in the figure as an example for readers to understand the aforementioned metal oxide film in the application of contacts in integrated circuits. As shown in FIG. 5, the contact of present invention is formed on a substrate 100, such as a P-type silicon wafer or an N-type doped region formed on a well region, on which silicide like nickel silicide (NiSi) may be formed. The substrate 100 is provided with a dielectric layer 104, such as a pre-metal dielectrics (PMD), made of phosphorus silicate glass (PSG) or borophosphosilicate glass (BPSG). A contact hole 106 is formed in the dielectric layer 104, with bottom exposing the substrate 100. A conformal N-type metal oxide film 102a is formed on the surface of contact hole 106 and the exposed substrate 100, which will directly contact the exposed substrate 100 to form a 2DEG in the substrate adjacent to the contact surface. The material of N-type metal oxide film 102a may be gallium oxide (Ga₂O₃), zinc oxide (ZnO), tin oxide (SnO₂), indium oxide (In₂O₃), titanium oxide (TiO₂), tungsten oxide (WO₃), indium tin oxide (ITO) and molybdenum oxide (MoO₃), etc., with a thickness between 0.8 nm and 10 nm. A conformal barrier layer 108 is formed on the N-type metal oxide film 102a, which may be a multilayer structure of titanium (Ti)/titanium nitride (TiN) to prevent metal ions in the contact from diffusing into the silicon substrate, as well as function as an adhesive layer between the contact plug and the N-type metal oxide film 102a. A contact plug 110 is formed on the barrier layer 108 and fills up the contact hole 106 as the conductive body of the contact, with material like tungsten (W). The aforementioned contact plug 110, barrier layer 108 and N-type metal oxide film 102a collectively constitute a contact structure with low contact resistance of the present invention. In addition, in the embodiment of present invention, the contact hole 106 may be subjected to an energetic particle etching treatment, such as a plasma treatment, dry etching process or wet etching process, before forming the N-type metal oxide film 102a, and an additional heat treatment with temperature less than 400° C. can be added to make the formed contact hole 106 having a relatively rough surface and a rounding corner 106a formed at the surface of opening, so as to facilitate the adhesion of the N-type metal oxide film 102a on the substrate 100 and enhance the electric field and carrier density at the junction. On the other hand, the contact structure for P-type semiconductor is also similar to the aforementioned contact, except that the metal oxide film is changed to a P-type metal oxide film 102b, and the substrate 100 is changed to a P-type doped region. No more details will be herein given.

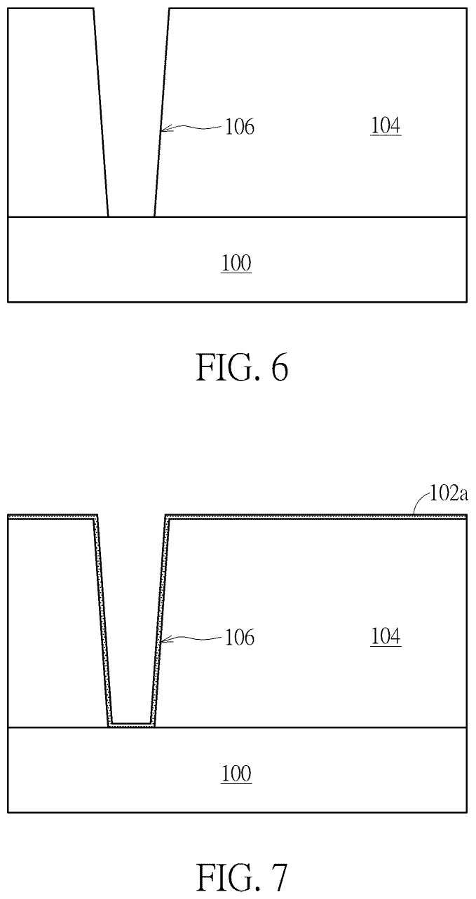

Please refer now to FIGS. 6-11 in sequence, which are schematic cross-sections illustrating a process flow of manufacturing the aforementioned contact structures in accordance with one embodiment of the present invention.

First, in FIG. 6, a substrate 100 is provided as a basis for forming the contact of present invention, such as a P-type silicon wafer or an N-type doped region formed on a well region, with a dielectric layer 104 formed thereon, such as a pre-metal dielectrics (PMD) made of borophosphosilicate glass (BPSG). Next, a photolithography process is performed to form a contact hole 106 in the dielectric layer 104, and the bottom of the contact hole 106 exposes the substrate 100. The photolithography process may be a high aspect ratio (HAR) contact hole process, which may include steps of forming a photoresist with contact hole pattern on the dielectric layer 104, and using the photoresist as a mask to perform a plasma etching process to remove the exposed dielectric layer 104 until the substrate 100 is exposed, thereby forming a contact hole 106 with a high aspect ratio.

Please refer to FIG. 7. After the contact hole 106 is formed, the contact hole 106 may then be subjected to an energetic particle etching process, such as plasma treatment, dry etching process or wet etching process, and an additional heat treatment with temperature less than 400° C. may be added to make the formed contact hole 106 having a relatively rough surface and a rounding corner formed at its openings to enhance the adhesion of the subsequent metal oxide film and further increase the carrier density. Afterwards, a conformal N-type metal oxide film 102a, such as a gallium oxide (Ga₂O₃) film, is formed on the surface of contact hole 106 and the exposed substrate 100, which will be in direct contact with the exposed substrate 100. In the embodiment of present invention, the N-type metal oxide film 102a may be formed through atomic layer deposition (ALD). Take the N-type metal oxide film 102a made of gallium oxide (Ga₂O₃) as an example, trimethylgallium and oxygen may be used as precursors to form multiple atomic films through multiple reactions and cycles, with the number of cycles preferably from 20 to 250 and the overall thickness between 0.8 nm and 10 nm, so as to achieve the best effect of reducing contact resistance and increasing electron mobility.

Please refer to FIG. 8. After the N-type metal oxide film 102a is formed, a barrier layer 108 and a contact plug 110 are formed sequentially on the surface of N-type metal oxide film 102a. In the embodiment, the material of barrier layer 108 may be titanium (Ti)/titanium nitride (TiN), which may be formed conformally on the surface of N-type metal oxide film 102a through physical vapor deposition (PVD). The contact plug 110 may be made of tungsten, which may fill up the contact hole 106 through chemical vapor deposition (CVD). After the aforementioned N-type metal oxide film 102a, barrier layer 108 and contact plug 110 are formed, a chemical mechanical planarization (CMP) process is performed to remove the portion above the top surface of dielectric layer 104, so as to form a contact in electrical contact with the substrate 100 in the dielectric layer 104. This is a contact for N-type semiconductor device (ex. NMOS) in an embodiment of present invention.

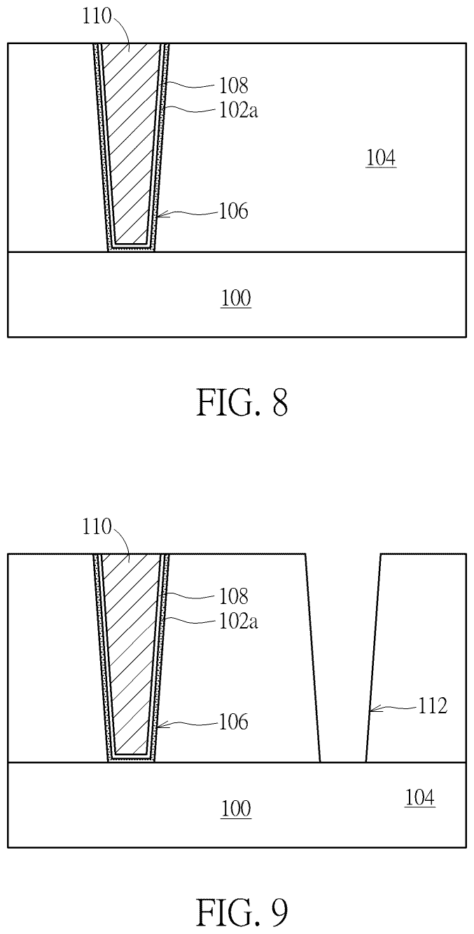

Please refer to FIG. 9. After the contacts required by N-type semiconductor devices are completed, the contacts for P-type semiconductor devices (ex. PMOS) are then processed. Similarly, a photolithography process is first performed to form a contact hole 112 in the dielectric layer 104. The bottom of contact hole 112 exposes the substrate 100, such as a P-type doped region formed in the substrate 100.

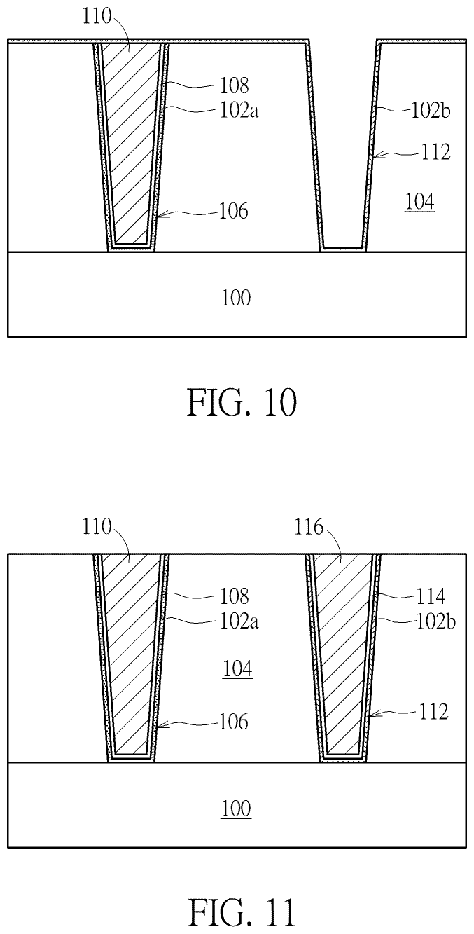

Please refer to FIG. 10. After the contact hole 112 is formed, similarly, the contact hole 112 is subjected to an energetic particle etching process, and a conformal P-type metal oxide film 102b, such as nickel oxide (NiO), is then formed on the processed surface of contact hole 112 and the exposed substrate 100 through multiple cycles and reactions of atomic layer deposition (ALD). The P-type metal oxide film 102b will be in direct contact with the exposed substrate 100.

Please refer to FIG. 11. After the P-type metal oxide film 102b is formed, a barrier layer 114 and a contact plug 116 are then formed sequentially on the surface of P-type metal oxide film 102b. Afterwards, a CMP process is performed to remove layer structures above the top surface of dielectric layer 104, so as to form the contacts in electrical contact with the substrate 100 in the dielectric layer 104. This is the contact for P-type semiconductor devices.

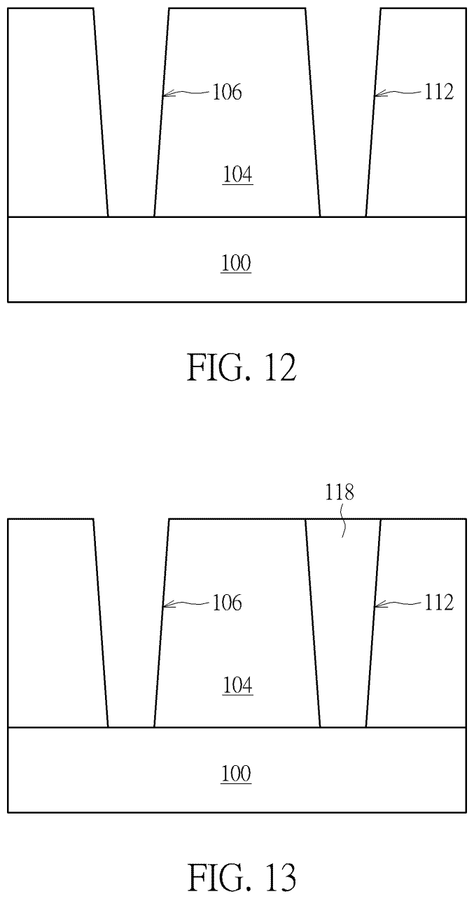

Please refer now to FIGS. 12-15 in sequence, which are schematic cross-sections illustrating a process flow of manufacturing the aforementioned contact structures in accordance with another embodiment of the present invention.

First, in FIG. 12, a substrate 100 is provided as a basis for forming the contact of present invention, such as a silicon wafer with N-type doped region and P-type doped region formed thereon. A dielectric layer 104 is formed on the substrate 100, such as a pre-metal dielectrics (PMD) made of borophosphosilicate glass (BPSG). Next, a photolithography process is performed to form a contact hole 106 and a contact hole 112 simultaneously in the dielectric layer 104, and the bottoms of two contact holes 106, 112 expose the substrate 100. The contact hole 106 and the contact hole 112 may be contact holes required respectively by NMOS and PMOS, with their bottoms exposing the N-type doped region and the P-type doped region respectively on the silicon substrate.

Please refer to FIG. 13. After the contact holes 106 and 112 are formed, a filling layer 118, such as a silicon nitride layer, is then filled into one of the contact holes to block the contact hole 112. In the embodiment, the function of filling layer 118 is to prevent subsequent contact material for NMOS device from being formed in the contact hole 112.

Please refer to FIG. 14. After the filling layer 118 is formed, the contact hole 106 may be first subjected to an energetic particle etching process, and an additional heat treatment with temperature less than 400° C. may be applied to make the formed contact hole 106 having a relatively rough surface and a rounding corner formed at its openings to further increase the carrier density. Afterwards, an N-type metal oxide film 102a, a barrier layer 108 and a contact plug 110 are formed sequentially on the surface of contact hole 106 and the exposed substrate 100, wherein the N-type metal oxide film 102a is in direct contact with the exposed substrate 100. A CMP process is then performed to remove layer structures above the top surface of dielectric layer 104, so as to form contacts in electrical contact with the substrate 100 in the dielectric layer 104. This is the contact required by NMOS.

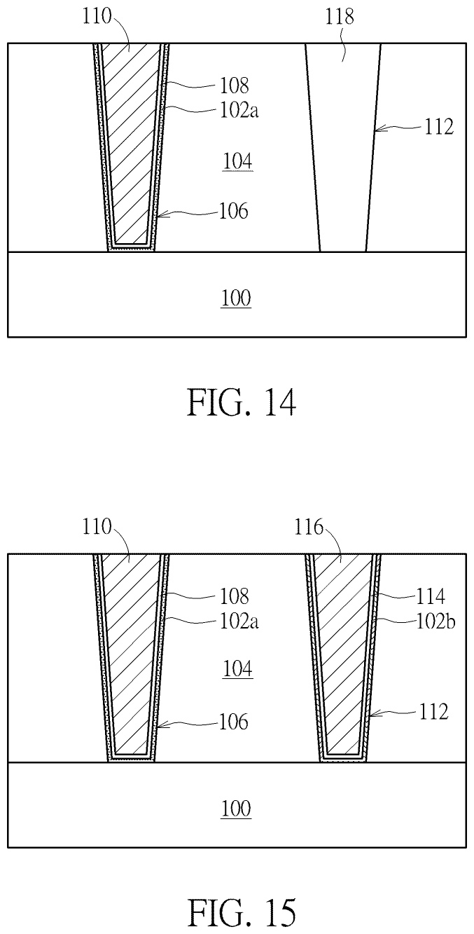

Please refer to FIG. 15. After the contacts for N-type semiconductor device is formed, a selective etching or ashing process is then performed to remove the filling layer 118 that fills up the contact hole 112. The same steps as that of the contacts for NMOS device are performed, including forming a P-type metal oxide film 102b, a barrier layer 114 and a contact plug 116 sequentially on the surface of contact hole 112, and a CMP is then performed to removes layer structures above the top surface of the dielectric layer 104, thereby forming contacts in electrical contact with the substrate 100 in the dielectric layer 104. This is the contact for P-type semiconductor devices.

It can be known from the process and structure shown above that the present invention features an N-type or P-type metal oxide film set between contact and semiconductor substrate to form a two-dimensional carrier gas at contact surface, so as to reduce contact resistance and improve carrier mobility, solving conventional problem of degenerate doping of silicon substrate, which are the non-obviousness and functionality of present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A contact structure with low contact resistance set on a substrate and in direct contact with the substrate, and the contact structure comprises:
a dielectric layer on the substrate;
a contact hole formed in the dielectric layer and exposing the substrate;
a metal oxide film on a surface of the contact hole and the exposed substrate;
a barrier layer on the metal oxide film; and
a contact plug on the barrier layer and filling up the contact hole;
wherein a two-dimensional carrier gas is formed in the substrate adjacent to a contact surface between the metal oxide film and the substrate.

2. The contact structure with low contact resistance of claim 1, wherein a material of the metal oxide film comprises gallium oxide (Ga₂O₃), zinc oxide (ZnO), tin oxide (SnO₂), indium oxide (In₂O₃), titanium oxide (TiO₂), tungsten oxide (WO₃), indium tin oxide (ITO) or molybdenum oxide (MoO₃), and the two-dimensional carrier gas is a two-dimensional electron gas.

3. The contact structure with low contact resistance of claim 2, wherein the substrate comprises an N-type doped silicon substrate or an indium gallium oxide (IGZO) substrate.

4. The contact structure with low contact resistance of claim 1, wherein a thickness of the metal oxide film is from 0.8 nm to 10 nm.

5. The contact structure with low contact resistance of claim 1, wherein the contact hole has a rounding corner at an opening on a top surface of the dielectric layer.

6. The contact structure with low contact resistance of claim 1, wherein the surface of the contact hole is rough surface.

7. The contact structure with low contact resistance of claim 1, wherein a material of the metal oxide film comprises nickel oxide (NiO), copper oxide (Cu₂O), cobalt oxide (Co₃O₄), chromium oxide (Cr₂O₃) or silver oxide (Ag₂O), and the two-dimensional carrier gas is two-dimensional hole gas.

8. The contact structure with low contact resistance of claim 7, wherein the substrate is P-type doped silicon substrate.

9. A method of manufacturing a contact structure with low contact resistance, comprising:
providing a substrate, and an interlayer dielectric layer is formed on the substrate;
forming a contact hole in the interlayer dielectric layer, and the contact hole exposes the substrate;
a metal oxide film is formed on a surface of the contact hole, and the metal oxide film is in direct contact with the substrate;
forming a barrier layer on a surface of the metal oxide film; and
forming a contact plug on the barrier layer, and the contact plug fills up the contact hole so that the contact plug, the barrier layer and the metal oxide film constitute a contact.

10. The method of manufacturing a contact structure with low contact resistance of claim 9, further comprising:
after the contact hole is formed and before the metal oxide film is formed, the substrate is subjected to an energetic particle treatment, thereby removing oxides on the surface of the contact hole and forming a rounding corner at an opening on a top surface of the dielectric layer.

11. The method of manufacturing a contact structure with low contact resistance of claim 9, wherein the contact hole comprises a first contact hole and a second contact hole, the metal oxide film comprises an N-type metal oxide film and a P-type metal oxide film, the barrier layer comprises a first barrier layer and a second barrier layer, the contact plug comprises a first contact plug and a second contact plug, and the contact comprises a first contact and a second contact.

12. The method of manufacturing a contact structure with low contact resistance of claim 11, further comprising:
forming the first contact hole firstly in the interlayer dielectric layer;
forming the N-type metal oxide film, the first barrier layer and the first contact plug sequentially in the first contact hole, so that the first contact plug, the first barrier layer and the N-type metal oxide film constitute the first contact;
forming the second contact hole in the interlayer dielectric layer after the first contact is formed, ; and
forming the P-type metal oxide film, the second barrier layer and the second contact plug sequentially in the second contact hole, so that the second contact plug, the second barrier layer and the P-type metal oxide film constitute the second contact.

13. The method of manufacturing a contact structure with low contact resistance of claim 11, further comprising:
forming the first contact hole and the second contact hole simultaneously in the interlayer dielectric layer;
filling up the second contact hole with a filling layer;
forming the N-type metal oxide film, the first barrier layer and the first contact plug sequentially in the first contact hole, so that the first contact plug, the first barrier layer and the N-type metal oxide film constitute the first contact;
removing the filling layer in the second contact hole after the first contact is formed; and
forming the P-type metal oxide film, the second barrier layer and the second contact plug sequentially in the second contact hole, so that the second contact plug, the second barrier layer and the P-type metal oxide film constitute the second contact.

14. The method of manufacturing a contact structure with low contact resistance of claim 11, wherein a material of the N-type metal oxide film comprises gallium oxide (Ga₂O₃), zinc oxide (ZnO), tin oxide (SnO₂), indium oxide (In₂O₃), titanium oxide (TiO₂), tungsten oxide (WO₃), indium tin oxide (ITO) or molybdenum oxide (MoO₃).

15. The method of manufacturing a contact structure with low contact resistance of claim 11, wherein a material of the P-type metal oxide film comprises nickel oxide (NiO), copper oxide (Cu₂O), cobalt oxide (Co₃O₄), chromium oxide (Cr₂O₃) or silver oxide (Ag₂O).

16. The method of manufacturing a contact structure with low contact resistance of claim 9, wherein the metal oxide film is formed through atomic layer deposition (ALD).

17. The method of manufacturing a contact structure with low contact resistance of claim 16, wherein a cycle number of the atomic layer deposition is from 20 to 250.

18. The method of manufacturing a contact structure with low contact resistance of claim 16, wherein a thickness of the metal oxide film is from 0.8 nm to 10 nm.
